(19) United States
(12) Patent Application Publication
(10) Pub. No.: US 2025/0280565 A1
(43) Pub. Date: Sep. 4, 2025

(54) THIN-FILM TRANSISTOR AND DISPLAY APPARATUS INCLUDING THE SAME

(71) Applicant: LG Display Co., Ltd., Seoul (KR)

(72) Inventor: Sungju CHOI, Paju-si (KR)

(73) Assignee: LG Display Co., Ltd., Seoul (KR)

(21) Appl. No.: 19/052,965

(22) Filed: Feb. 13, 2025

(30) Foreign Application Priority Data
Feb. 29, 2024 (KR) 10-2024-0030015

(51) Int. Cl. H10D 30/67

(52) U.S. Cl. CPC H10D 30/6723; H10D 30/6746

(57) ABSTRACT

A display apparatus including a light-emitting element and a thin-film transistor coupled to the thin-film transistor is described. A thin-film transistor includes a substrate. The thin-film transistor includes a light-blocking layer disposed on the substrate. The thin-film transistor includes a first buffer layer disposed on the light-blocking layer. The thin-film transistor includes an active layer disposed on the first buffer layer. The thin-film transistor includes a gate electrode disposed on the active layer. The thin-film transistor includes at least one conductive structure disposed between the light-blocking layer and the active layer. The thin-film transistor includes a second buffer layer disposed between the light-blocking layer and the active layer so as to cover the conductive structure.

### CROSS-REFERENCE TO RELATED APPLICATION

This application claims priority from Korean Patent Application No. 10-2024-0030015 filed on Feb. 29, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a thin-film transistor and a display apparatus including the thin-film transistor.

### Description of the Related Art

Display apparatus are applied to various electronic devices such as TVs (Televisions), smartphones, laptops, and tablets. To this end, research is being conducted to develop smaller, lighter, and lower power consuming display devices.

Examples of the display apparatus include a liquid crystal display apparatus (LCD), a field emission display apparatus (FED), and an organic light emitting display apparatus (OLED).

A transistor is used as an element that controls each of a plurality of pixels included in the display apparatus. The display apparatus may include at least one thin-film transistor.

### BRIEF SUMMARY

Various embodiments of the present disclosure provide a thin-film transistor capable of achieving a high S-factor without reducing a driving current, and a display apparatus including the same.

Various embodiments of the present disclosure provide a thin-film transistor including different areas having capacitances of different magnitudes in one thin-film transistor, and a display apparatus including the same.

Various embodiments of the present disclosure provide a thin-film transistor capable of advantageously performing grayscale expression and a display apparatus including the same.

Technical benefits of the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

The thin-film transistor according to an embodiment of the present disclosure may include: a substrate; a light-blocking layer disposed on the substrate; a first buffer layer disposed on the light-blocking layer; an active layer disposed on the first buffer layer; a gate electrode disposed on the active layer; at least one conductive structure disposed between the light-blocking layer and the active layer; and a second buffer layer disposed between the light-blocking layer and the active layer so as to cover the conductive structure.

A display apparatus according to an embodiment of the present disclosure may include a light-emitting element; and a thin-film transistor connected to the light-emitting element, wherein the thin-film transistor may include: a substrate; a light-blocking layer disposed on the substrate; a first buffer layer disposed on the light-blocking layer; an active layer disposed on the first buffer layer; a gate electrode disposed on the active layer; at least one conductive structure disposed between the light-blocking layer and the active layer; and a second buffer layer disposed between the light-blocking layer and the active layer so as to cover the conductive structure.

According to an embodiment of the present disclosure, the thin-film transistor may have capacitances having different magnitudes in different areas arranged in the width direction of the channel area, such that the S-factor value may be increased without reducing the total driving current Ion.

Accordingly, the high S-factor value required for the low-grayscale expression may be secured without reducing the driving current. Thus, the thin-film transistor may advantageously perform various grayscale expressions.

Furthermore, according to an embodiment of the present disclosure, the buffer layer may be formed to have the structure to have capacitances of different magnitudes in a single thin-film transistor. Thus, the thin-film transistor may not be subjected to the trade-off relationship between the S-factor and the driving current, which may be applied to the conventional thin-film transistor in which the buffer layer is formed as a single flat layer.

Accordingly, the reliability of the thin-film transistor may be increased, and the production energy saving effect may be realized through process optimization.

In addition, the conductive structure including the semiconductor pattern may be disposed so as to face the active layer, that is, overlap therewith, and thus may absorb the ultraviolet rays the energy of which is corresponding to a band gap energy of a semiconductor material of the semiconductor structure, such that the reliability of the active layer may be improved.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a schematic diagram of a display apparatus according to an embodiment of the present disclosure.

FIG. 2 is a diagram showing a circuit of a pixel area in a display apparatus according to an embodiment of the present disclosure.

FIG. 3 is a plan view of a thin-film transistor according to an embodiment of the present disclosure.

FIG. 4 is a cross-sectional view taken along a line 4-4′ of FIG. 3.

FIGS. 5A to 5D are cross-sectional views illustrating a method for manufacturing a thin-film transistor according to an embodiment of the present disclosure.

FIG. 6 is a plan view of a thin-film transistor according to another embodiment of the present disclosure.

FIG. 7 is a cross-sectional view taken along a line 7-7′ of FIG. 6.

FIG. 8 shows a variant example of a thin-film transistor according to another embodiment of the present disclosure.

FIG. 9 is a plan view of a thin-film transistor according to still another embodiment of the present disclosure.

FIG. 10 is a cross-sectional view taken along a line 10-10′ of FIG. 9.

FIG. 11 is a plan view of a thin-film transistor according to still yet another embodiment of the present disclosure.

FIG. 12 is a cross-sectional view taken along a line 12-12′ of FIG. 11.

FIG. 13 shows a variant example of a thin-film transistor according to still yet another embodiment of the present disclosure.

FIG. 14 is a graph of a current-voltage curve of a thin-film transistor.

FIG. 15A is a diagram showing a structure for controlling a capacitance ratio of a thin-film transistor.

FIG. 15B is a graph showing a trade-off relationship between a S-factor and a driving current of a thin-film transistor.

FIG. 16 is a cross-sectional view showing one of pixel areas of a display apparatus including a thin-film transistor according to an embodiment of the present disclosure in an enlarged manner.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc., disclosed in the drawings for illustrating embodiments of the present disclosure are illustrative, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of element may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

In descriptions of temporal relationships, for example, temporal precedent relationships between two events such as “after,” “subsequent to,” “before,” etc., another event may occur therebetween unless “directly after,” “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, a display apparatus according to each of embodiments of the present disclosure is described with reference to the attached drawings.

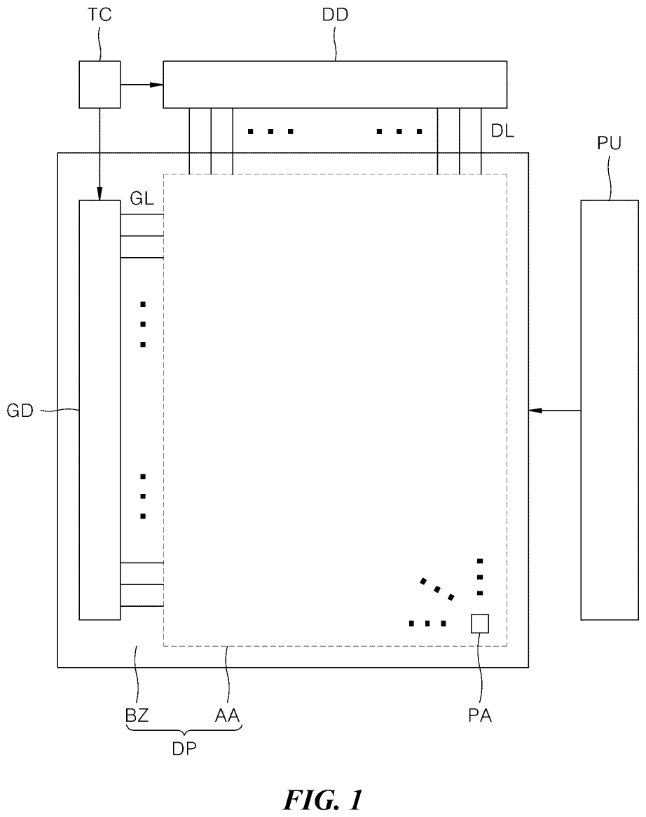

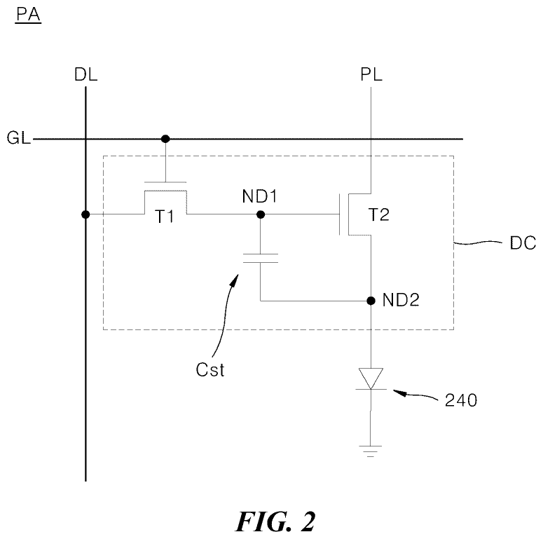

FIG. 1 is a diagram showing a schematic diagram of a display apparatus according to an embodiment of the present disclosure. FIG. 2 is a diagram showing a circuit of a pixel area in a display apparatus according to an embodiment of the present disclosure.

Referring to FIGS. 1 and 2, the display apparatus according to an embodiment of the present disclosure may include a display panel DP. The display panel DP may generate an image or video provided to a user. For example, a plurality of pixel areas PA may be disposed in the display panel DP. Various signals may be transmitted to each of the pixel areas PA via signal lines GL, DL, and PL. For example, the signal lines GL, DL, and PL may include gate lines GL, data lines DL, and power voltage supply lines PL.

The gate lines GL may sequentially apply a gate signal to each pixel area PA. The data lines DL may apply a data signal to each pixel area PA. The power voltage supply lines PL may supply a power voltage to each pixel area PA. The gate lines GL may be electrically connected to a gate driver GD. The data lines DL may be electrically connected to a data driver DD.

The gate driver GD and the data driver DD may be controlled by a timing controller TC. For example, the gate driver GD may receive clock signals, reset signals, and a start signal from the timing controller TC, and the data driver DD may receive digital video data and a source timing signal from the timing controller TC. The power voltage supply lines PL may be electrically connected to a power unit PU.

The display panel DP may include an active area AA where pixel areas PA are disposed and a bezel area BZ disposed outside the active area AA. The bezel area BZ may be disposed outside the pixel areas PA. For example, the active area AA may be surrounded with the bezel area BZ. At least one of the gate driver GD, the data driver DD, the timing controller TC, and the power unit PU may be disposed on the bezel area BZ of the display panel DP. For example, the display apparatus according to an embodiment of the present disclosure may be a GIP (Gate In Panel) type display apparatus in which the gate driver GD is formed on the bezel area BZ of the display panel DP. Each of the signal lines GL, DL, and PL may include a portion disposed on the bezel area BZ. The bezel area BZ may be referred to as a non-display area.

Each pixel area PA may emit light of a specific color. For example, the pixel areas PA may be implemented to emit light of different colors, such as red (R), green (G), and blue (B) color lights. Alternatively, the pixel areas PA may be implemented to emit light of the same color, such as white (W) light.

A light-emitting element 240 and a pixel driving circuit DC electrically connected to the light-emitting element 240 may be disposed within each pixel area PA.

The signal lines GL, DL, and PL may be electrically connected to the pixel driving circuit DC of each pixel area PA. For example, the pixel driving circuit DC of each pixel area PA may be electrically connected to one of the gate lines GL, one of the data lines DL, and one of the power voltage supply lines PL. The pixel driving circuit DC of each pixel area PA may supply a driving current corresponding to a data signal to the light-emitting element 240 of the pixel area PA for one frame period in response to the gate signal.

The pixel driving circuit DC of each pixel area PA may include a first thin-film transistor T1, a second thin-film transistor T2, and a storage capacitor Cst.

The first thin-film transistor T1 may be, for example, a switching transistor. The first thin-film transistor T1 may apply a voltage of the data line DL to a first node ND1. The first thin-film transistor T1 may be turned on or off based on a scan signal. The first node ND1 may be connected to a gate electrode of the second thin-film transistor T2.

The second thin-film transistor T2 may be, for example, a driving thin-film transistor. The second thin-film transistor T2 may operate so that a driving current flows based on the data voltage stored in the storage capacitor Cst. The second thin-film transistor T2 may be turned on based on the data voltage to control the current flowing through the light-emitting element 240 so that an image or video may be displayed. The light-emitting element 240 may emit light under the current flow through the second thin-film transistor T2.

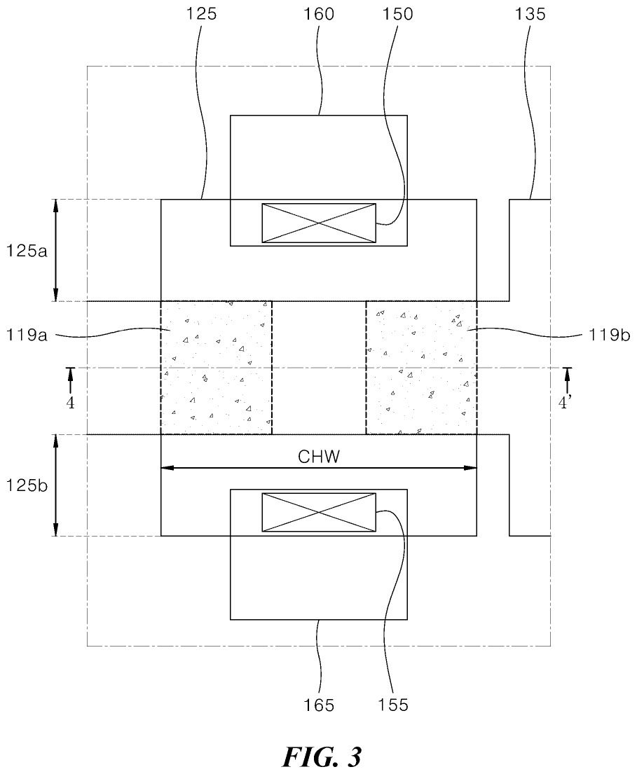

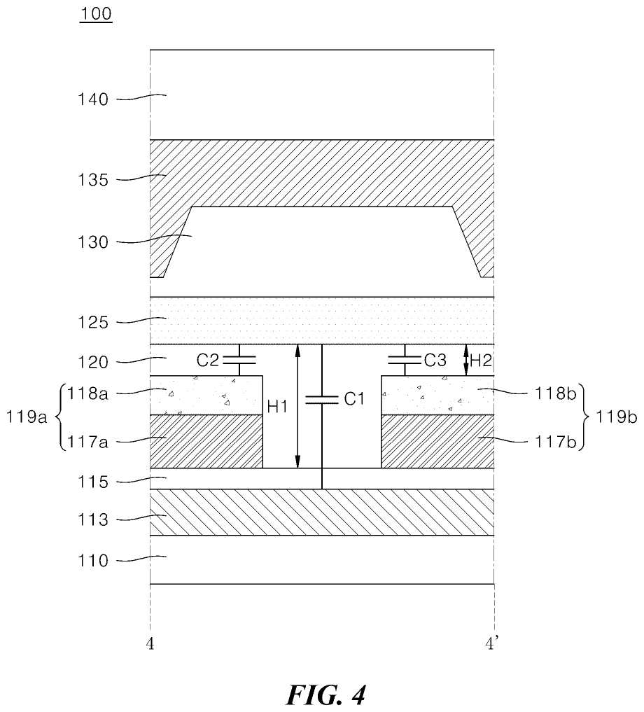

Hereinafter, a thin-film transistor according to an embodiment of the present disclosure will be described with reference to FIG. 3 and FIG. 4. The thin-film transistor as described in the present disclosure may be a driving thin-film transistor as at least the second thin-film transistor T2 among the first thin-film transistor TI and the second thin-film transistor T2. However, embodiments of the present disclosure are not limited thereto.

FIG. 3 is a plan view of a thin-film transistor according to one embodiment of the present disclosure. FIG. 4 is a cross-sectional view taken along a line 4-4′ of FIG. 3.

Referring to FIG. 3 and FIG. 4, a light-blocking layer 113 may be disposed on a substrate 110. The substrate 110 may include glass or plastic. The plastic substrate may include polyimide. However, embodiments of the present disclosure are not limited thereto.

The thin-film transistor as described in the present disclosure may be a driving thin-film transistor. However, embodiments of the present disclosure are not limited thereto. The driving thin-film transistor may be turned on based on the voltage to control the current flowing though the light-emitting element to display an image.

The light-blocking layer 113 may be disposed to overlap the active layer 125 in a vertical direction. For example, the light-blocking layer 113 may have the same area as that of the active layer 125 or a larger area than that of the active layer 125.

The light-blocking layer 113 may block light incident thereto from an outside. The active layer 125 of the thin-film transistor 100 may be protected by the light-blocking layer 113. To this end, the light-blocking layer 113 may include a material that is electrically conductive and may block light incident thereto from the outside. For example, the light-blocking layer 113 may be formed as a single layer or a stack of multiple layers made of one or more opaque metal materials selected from the group of molybdenum (Mo), aluminum (Al), titanium (Ti), and copper (Cu), and an alloy thereof. However, the present disclosure is not limited thereto. The light-blocking layer 113 may include a low-reflective metal material.

A first buffer layer 115 may be disposed on the light-blocking layer 113. The first buffer layer 115 may include, but is not limited to, silicon oxide (SiOₓ) or silicon nitride (SiNₓ). For example, the first buffer layer 115 may be a signal layer or a multilayer in which a plurality of insulating films is alternately stacked.

The first buffer layer 115 may cover an upper surface of the light-blocking layer 113. For example, the first buffer layer 115 may entirely cover the upper surface of the light-blocking layer 113. The first buffer layer 115 may reduce or prevent penetration of moisture, oxygen, or impurities through the substrate 110 into the thin film transistor 100 to protect the thin film transistor 100.

A conductive pattern 117a and 117b may be disposed on the first buffer layer 115. The conductive pattern 117a and 117b may include one or more conductive patterns. For example, the conductive pattern 117a and 117b may include the first conductive pattern 117a and the second conductive pattern 117b. The first conductive pattern 117a and the second conductive pattern 117b may be positioned on the light-blocking layer 113 while the first buffer layer 115 is disposed between the first conductive pattern 117a and the second conductive pattern 117b and the light-blocking layer 113.

The first conductive pattern 117a and the second conductive pattern 117b may be arranged so as to be spaced apart from each other such that a space is defined therebetween.

Each of the first conductive pattern 117a and the second conductive pattern 117b may include an electrically conductive material. For example, each of the first conductive pattern 117a and the second conductive pattern 117b may be formed as a single layer or a stack of multiple layers made of one or more selected from a group of opaque metal materials such as molybdenum (Mo), aluminum (Al), titanium (Ti), and copper (Cu), and an alloy thereof. However, embodiments of the present disclosure are not limited to these materials.

A first semiconductor pattern 118a and a second semiconductor pattern 118b may be disposed on an upper surface of the first conductive pattern 117a and an upper surface of the second conductive pattern 117b, respectively.

The first semiconductor pattern 118a may be disposed on the first conductive pattern 117a to constitute a first conductive structure 119a, while the second semiconductor pattern 118b may be disposed on the second conductive pattern 117b to constitute a second conductive structure 119b. That is, the first conductive structure 119a may include the first semiconductor pattern 118a and the first conductive pattern 117a. The second conductive structure 119b may include the second semiconductor pattern 118b and the second conductive pattern 117b.

Each of the first semiconductor pattern 118a and the second semiconductor pattern 118b may include a silicon-based semiconductor material. Each of the first semiconductor pattern 118a and the second semiconductor pattern 118b may include amorphous silicon doped with a first conductive impurity. For example, the first conductive impurity may include an n-type impurity. The n-type impurity may include phosphorus (P), arsenic (As), or antimony (Sb). In another example, each of the first semiconductor pattern 118a and the second semiconductor pattern 118b may include a semiconductor material doped with the first conductive impurity.

A second buffer layer 120 may be disposed on the first buffer layer 115, the first conductive structure 119a, and the second conductive structure 119b. The second buffer layer 120 may fill the space between the first conductive structure 119a and the second conductive structure 119b.

Accordingly, a portion of the second buffer layer 120 may be formed to have a first thickness H1 in the space area. A portion of the second buffer layer 120 may cover an upper surface of each of the first conductive structure 119a and the second conductive structure 119b so as to have a second thickness H2. The second buffer layer 120 may include silicon oxide (SiOₓ) or silicon nitride (SiNₓ). However, embodiments of the present disclosure are not limited thereto.

An active layer 125 may be disposed on the second buffer layer 120. The active layer 125 may include an oxide semiconductor material. For example, the active layer 125 may include an oxide semiconductor material such as indium gallium zinc oxide (IGZO) or indium zinc oxide (IZO). However, embodiments of the present disclosure are not limited thereto.

One side edge of the first conductive structure 119a may be aligned with one side edge of the active layer 125. However, embodiments of the present disclosure are not limited thereto. The other side edge of the second conductive structure 119b may be aligned with the other side edge of the active layer 125. However, embodiments of the present disclosure are not limited thereto.

Each of the first semiconductor pattern 118a of the first conductive structure 119a and the second semiconductor pattern 118b of the second conductive structure 119b may be positioned so as to face the active layer 125, that is, so as to overlap therewith in the vertical direction. The first semiconductor pattern 118a and the second semiconductor pattern 118b may further prevent external light from being incident on the active layer 125.

The light-blocking layer 113 may be disposed on the substrate 110 so as to prevent the light from the outside out of the substrate 110 from being incident on the active layer 125. However, while the thin-film transistor is operating, the active layer 125 may be exposed to light. Alternatively, the active layer 125 may be exposed to light, particularly, ultraviolet light due to diffuse reflection, etc.

An oxide semiconductor constituting the active layer 125 has instability such as NBIS (negative bias illumination stress) which undesirably increases current when the oxide semiconductor is exposed to the light.

Each of the first semiconductor pattern 118a and the second semiconductor pattern 118b may absorb ultraviolet rays the energy of which is corresponding to a band gap energy of the semiconductor material thereof. Accordingly, in an embodiment of the present disclosure, the light which may be incident on the active layer 125 may be absorbed by the first semiconductor pattern 118a and the second semiconductor pattern 118b which are positioned so as to face the active layer 125, so that the reliability of the active layer 125 may be prevented from being deteriorated.

A gate insulating layer 130 may be disposed on the active layer 125. The gate insulating layer 130 may include a single layer or a stack of multiple layers made of silicon oxide (SiOₓ) or silicon nitride (SiNₓ). However, embodiments of the present disclosure are not limited thereto.

A gate electrode 135 may be disposed on the gate insulating layer 130. The gate electrode 135 may be positioned to overlap with the active layer 125 in the vertical direction.

Referring to FIG. 3, the gate electrode 135 may have a smaller width in a direction perpendicular to the CHW (channel area width) direction than that of the active layer 125. A portion of the active layer 125 that overlaps with the gate electrode 135 in the vertical direction may act as a channel area. A first portion 125a of the active layer 125 that does not overlap with the gate electrode 135 may act as a source area, and a second portion 125b of the active layer 125 that does not overlap with the gate electrode 135 may act as a drain area. However, the present disclosure is not limited thereto. For example, the first portion 125a may act as a drain area, and the second portion 125b may act as a source area.

The first conductive structure 119a and the second conductive structure 119b may be positioned to be spaced apart from each other in a width CHW direction of the channel area, the spacing therebetween is filled with the second buffer layer 120. In this case, in the width CHW direction of the channel area, an area where the first conductive structure 119a is disposed may be a first area, and an area where the second conductive structure 119b is disposed may be a second area. An aera where the first conductive structure 119a and the second conductive structure 119c are absent may be a third area. That is, the first to third areas may be arranged in the width CHW direction of the channel area.

Referring to FIG. 3, the first conductive structure 119a and the second conductive structure 119b may be positioned to be spaced apart from each other in the width CHW direction of the channel area.

An interlayer insulating layer 140 may be disposed on the gate electrode 135. The interlayer insulating layer 140 may include a single layer or a stack of multiple layers made of silicon oxide (SiOₓ) or silicon nitride (SiNₓ). However, the present disclosure is not limited thereto.

A first electrode 160 and a second electrode 165 may be disposed on the interlayer insulating layer 140. The first electrode 160 may be connected to the first area 125a as one side area in a direction perpendicular to the CHW direction of the active layer 125 via a first contact hole 150 penetrating through the interlayer insulating layer 140 and the gate insulating layer 130. Furthermore, the second electrode 165 may be connected to the second area 125b as the other side area in the direction perpendicular to the CHW direction of the active layer 125 via a second contact hole 155 penetrating through the interlayer insulating layer 140 and the gate insulating layer 130.

The thin-film transistor 100 may be composed of the active layer 125, the gate electrode 135, the first electrode 160, and the second electrode 165 formed in the above-described manner.

According to an embodiment of the present disclosure, the thin-film transistor 100 may have a first capacitance C1 composed of the portion of the second buffer layer 120 having a first thickness H1 and the first buffer layer 115 disposed between the light-blocking layer 113 and the active layer 125 in the third area.

In the first area, the portion of the second buffer layer 120 having a second thickness H2 may be disposed between the active layer 125 and the first conductive structure 119a such that a second capacitance C2 may be formed. In addition, in the second area, the portion of the second buffer layer 120 having the second thickness H2 may be disposed between the active layer 125 and the second conductive structure 119b such that a third capacitance C3 may be formed.

In this case, the first thickness H1 of the portion of the second buffer layer 120 disposed in the space between the first conductive structure 119a and the second conductive structure 119b may be larger than the second thickness H2. In addition, the first capacitance C1 may be formed between the light-blocking layer 113 and the active layer 125 based on a sum of a thickness of the first buffer layer 115 and the first thickness HI of the second buffer layer 120.

In this regard, the second capacitance C2 may be formed in the first area based on the second thickness H2 of the portion of the second buffer layer 120 that is smaller than in the first thickness H1 in the third area. Furthermore, the third capacitance C3 may be formed in the second area based on the second thickness H2 of the portion of the second buffer layer 120 that is smaller than in the first thickness H1 in the third area.

Accordingly, a magnitude of the first capacitance C1 of the third area may be greater than a magnitude of each of the second capacitance C2 of the first area and the third capacitance C3 of the second area. The magnitude of the second capacitance C2 and the magnitude of the third capacitance C3 may be equal to each other.

Furthermore, the second capacitance C2 of the first area and the third capacitance C3 of the second area may be formed symmetrically with each other and may be respectively disposed on both opposing sides of the first capacitance C1 of the third area interposed therebetween.

In the third area where the first capacitance C1 is formed, the threshold voltage may be larger, while in each of the first area where the second capacitance C2 is formed and the second area where the third capacitance C3 is formed, the threshold voltage may be smaller compared to that in the third area. The portion of the second buffer layer 120 in the third area is thicker than the portion of the second buffer layer 120 in each of the first area and the second area, so that the driving current Ion may be the first magnitude of current in the third area. In addition, the portion of the second buffer layer 120 in each of the first area and the second area is thinner than the portion of the second buffer layer 120 in the third area, so that the driving current Ion may be the second magnitude of current larger than the first magnitude of current in each of the first and second areas.

Accordingly, the driving current Ion of the thin-film transistor 100 may be a third magnitude of current as a sum of the first magnitude of current and the second magnitude of currents based on the current characteristics of the transistors connected in parallel with each other in the channel width CHW direction.

Therefore, while the driving current Ion may not be lowered, the S-factor may be controlled to have a high value. Thus, while the switching characteristics of the thin-film transistor may be maintained, low-gray level expression may be advantageously achieved.

The S-factor is referred to as “subthreshold region slope” and indicates a voltage required when the current increases by 10 times. In a graph (I-V curve) showing characteristics of a drain current relative to a gate voltage, the S-factor value is a reciprocal value of a slope of the graph (I-V curve) in a range below the threshold voltage.

A small S-factor value means that the slope of the characteristic graph I-V of the drain current relative to the gate voltage is large. Therefore, the thin-film transistor may be turned on even under a small gate voltage, and the switching characteristics of the thin-film transistor may be improved. On the other hand, since the drain current increase fast as the gate voltage increases, it may be difficult to express sufficient gray levels.

Conversely, a large S-factor value means that the slope of the characteristic graph I-V of the drain current relative to the gate voltage is small. Therefore, the switching characteristics of the thin-film transistor may deteriorate due to decrease in an on/off response speed of the thin-film transistor, while sufficient grayscale expression may be achieved because the drain current increase slowly as the gate voltage increases.

The S-factor value may increase or decrease depending on a capacitance ratio C_{BUF}/C_{GI} between a capacitance C_{BUF} between the active layer 125 and the light-blocking layer 113, and a capacitance C_{BUF} between the gate electrode 135 and the active layer 125.

The S-factor value based on the capacitance ratio C_{BUF}/C_{GI} may be determined based on a following [Equation 1]:

S-factor∝(1+C_{BUF}/C_{GI}) Equation 1

According to the [Equation 1], the S-factor value may increase as the magnitude of the capacitance C_{BUF} between the active layer 125 and the first buffer layer 115 increases.

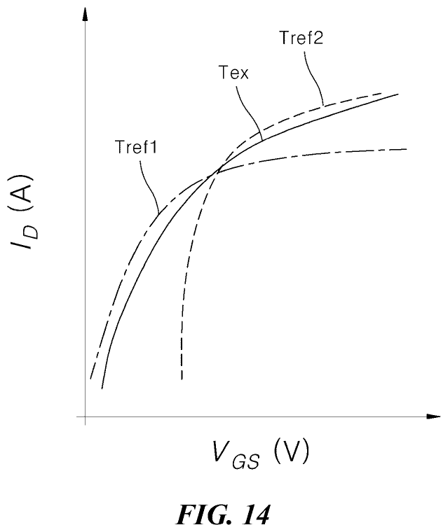

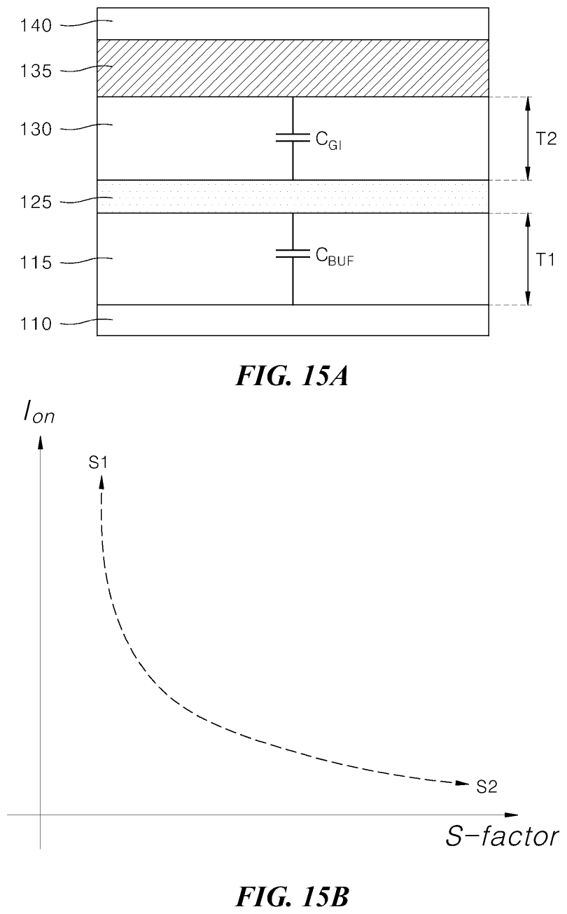

FIG. 14 is a graph of the current-voltage curve of the thin-film transistor. FIG. 15A is a diagram showing a structure for controlling the capacitance ratio of the thin-film transistor. FIG. 15B is a graph showing a trade-off relationship between the S-factor and the driving current of the thin-film transistor.

Referring to FIG. 15A, schemes for increasing the magnitude of the capacitance C_{BUF} between the active layer 125 and the light-blocking layer 113 may include increasing the thickness T1 of the first buffer layer 115 to be larger than the thickness T1 of the gate insulating layer 130. In another example, a scheme for increasing the magnitude of the capacitance C_{BUF} between the active layer 125 and the light-blocking layer 113 may include changing a material of the first buffer layer 115 so as to change a dielectric constant thereof.

As the magnitude of the capacitance C_{BUF} between the active layer 125 and the first buffer layer 115 increases, the S-factor value may increase, while the driving current Ion magnitude decreases. Thus, the S-factor value and the driving current Ion has a trade-off relationship.

The magnitude of the driving current Ion based on the magnitude of the capacitance C_{BUF} between the active layer 125 and the first buffer layer 115 may be determined based on a following [Equation 2]:

Driving current Ion∝(1+C_{BUF}/C_{GI})⁻¹ Equation 2

According to the above [Equation 2], the driving current Ion may decrease as the magnitude of the capacitance C_{BUF} between the active layer 125 and the first buffer layer 115 increases. When the driving current Ion decreases, an operation efficiency of a compensation circuit may decrease. When the operation efficiency of the compensation circuit decreases, a defect such as a panel stain may occur.

Referring to FIG. 15B, it may be identified that the S-factor and the driving current Ion of the thin-film transistor have a trade-off relationship in which the magnitude of current of the driving current Ion increases when the S-factor decreases as indicated by S1, and the magnitude of current of the driving current Ion decreases when the S-factor increases as indicated by S2.

Referring to FIG. 14, the driving current Ion of Comparative Example 1 Tref1 in which the thickness of the first buffer layer 115 is reduced so as to have only a single second capacitance C2 may be represented as a first magnitude of current. In addition, the driving current Ion of Comparative Example 2 Tref2 in which the thickness of the first buffer layer 115 is increased so as to have only a single first capacitance C1 may be represented as a second magnitude of current.

In this regard, according to an embodiment of the present disclosure, in one thin-film transistor 100, the second capacitance C2 of the first area and the third capacitance C3 of the second area may be formed symmetrically with each other around the first capacitance C1 of the third area interposed therebetween. Accordingly, according to the current characteristics of the parallel connected transistors, a third magnitude of current Tex as the sum of the first magnitude of current and the second magnitude of current may be the driving current Ion of the thin-film transistor according to an embodiment of the present disclosure.

Accordingly, according to an embodiment of the present disclosure, a high S-factor value may be secured without a decrease in the magnitude of current of the driving current Ion, so that the thin-film transistor may achieve sufficient low-gray level expression. The high S-factor required for realizing sufficient low-gray level expression when the active layer 125 is made of the oxide semiconductor material without the need of apply a very small current to the thin-film transistor may be secured.

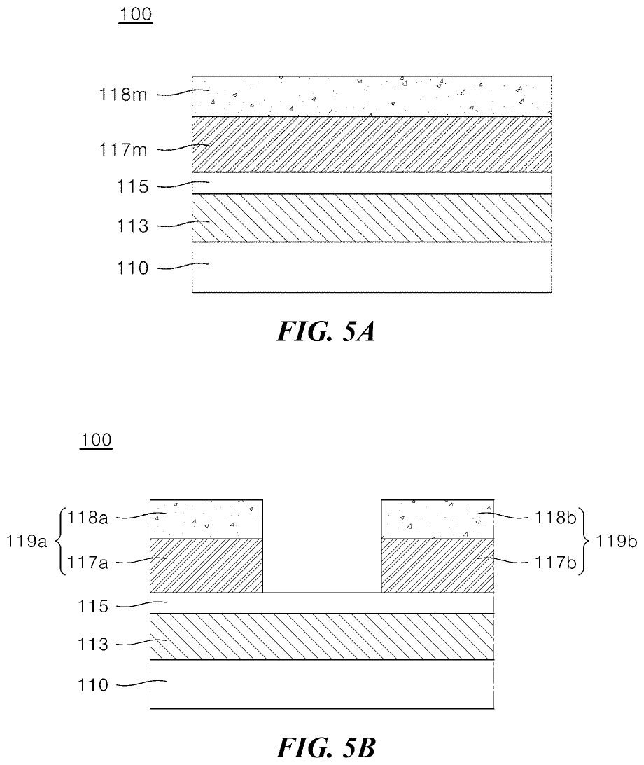

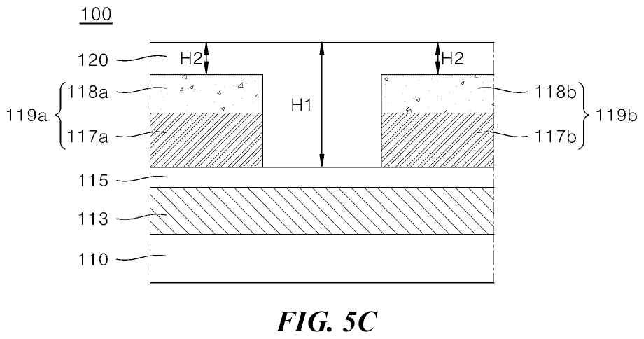

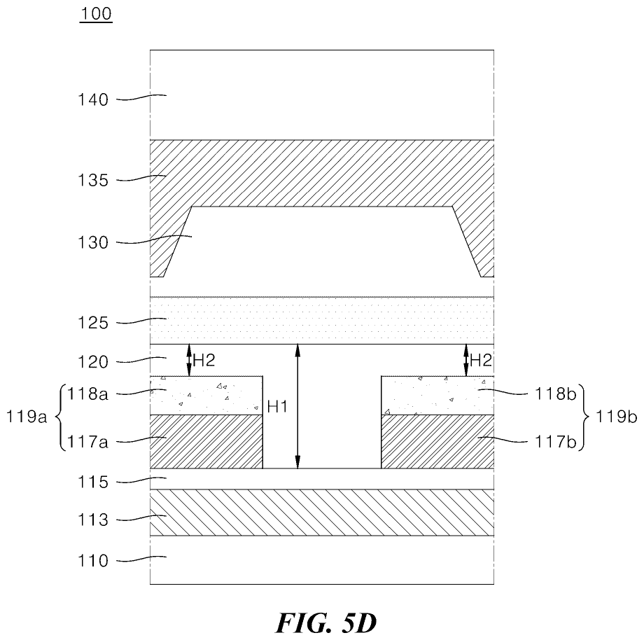

FIGS. 5A to 5D are cross-sectional views illustrating a method for manufacturing a thin-film transistor according to an embodiment of the present disclosure. In FIGS. 5A to 5E, the same reference numerals are assigned to the components having same reference numerals of the thin-film transistors as described above with reference to FIGS. 3 and 4, and the descriptions thereof are simplified or omitted.

Referring to FIG. 5A, the light-blocking layer 113, the first buffer layer 115, a conductive layer 117m, and a semiconductor material layer 118m doped with a first conductive impurity are formed on the substrate 110. The light-blocking layer 113, the first buffer layer 115, the conductive layer 117m, and the semiconductor material layer 118m may be stacked or arranged vertically and upwardly on the substrate 110. The conductive layer 117m may include a material that has electrical conductivity and may block light incident from the outside. For example, the conductive layer 117m may be formed as a single layer or a stack of multiple layers made of one selected from a group of metal materials such as molybdenum (Mo), aluminum (Al), titanium (Ti), and copper (Cu), and an alloy thereof. However, embodiments of the present disclosure are not limited thereto.

The semiconductor material layer 118m may include an amorphous silicon layer. However, the present disclosure is not limited thereto. For example, the semiconductor material layer 118m may include a semiconductor material that may be doped with a first conductive impurity. The first conductive impurity may include an n-type impurity. The n-type impurity may include phosphorus (P), arsenic (As), or antimony (Sb).

Referring to FIG. 5B, an etching process is performed on the semiconductor material layer 118m (see FIG. 5A), and the conductive layer 117m (see FIG. 5A). In the etching process, each of the conductive layer 117m and the semiconductor material layer 118m may be divided into a plurality of structures 119a and 119b. The plurality of structures may include the first conductive structure 119a and the second conductive structure 119b.

The first conductive structure 119a may include the first conductive pattern 117a, and the first semiconductor pattern 118a on the first conductive pattern 117a. The second conductive structure 119b may include the second conductive pattern 117b, and the second semiconductor pattern 118b on the second conductive pattern 117b.

The first conductive structure 119a and the second conductive structure 119b may be positioned to be spaced apart from each other. A portion of the first buffer layer 115 in the space between the first conductive structure 119a and the second conductive structure 119b may be exposed upwardly. For example, the area where the first conductive structure 119a is disposed may be the first area, and the area where the second conductive structure 119b is disposed may be the second area. The area between the first conductive structure 119a and the second conductive structure 119b may be the third area.

Referring to FIG. 5C, the second buffer layer 120 is formed on the first conductive structure 119a and the second conductive structure 119b. The second buffer layer 120 may fill the space defined between the first conductive structure 119a and the second conductive structure 119b. In addition, the second buffer layer 120 may cover the upper surface of each of the first semiconductor pattern 119a and the second semiconductor pattern 119b.

Accordingly, the second buffer layer 120 may have different thicknesses in the first area, the second area, and the third area. For example, the second buffer layer 120 may have the first thickness H1 in the third area defined between the first conductive structure 119a and the second conductive structure 119b. In addition, the second buffer layer 120 may be formed on the upper surface of the first conductive structure 119a so as to have the second thickness H2 in the first area. The second buffer layer 120 may be formed on the upper surface of the second conductive structure 119b so as to have the second thickness H2 in the second area. The first thickness H1 of the portion of the second buffer layer 120 disposed in the third area may be larger than the second thickness H2 of the portion of the second buffer layer 120 disposed in each of the first area and the second area. The second buffer layer 120 may have the same thickness in the first area and the second area. However, embodiments of the present disclosure are not limited thereto.

Referring to FIG. 5D together with FIG. 3, the active layer 125 is formed on the second buffer layer 120. The active layer 125 may include an oxide semiconductor material.

The gate insulating layer 130 and the gate electrode 135 may be formed on the active layer 125. The gate electrode 135 may be positioned to overlap with the active layer 125 in the vertical direction. A portion of the active layer 125 overlapping the gate electrode 135 may be the channel area. The first portion 125a of the active layer 125 that does not overlap with the gate electrode 135 may be a source area, and the second portion 125b of the active layer 125 that does not overlap with the gate electrode 135 may be a drain area. The source area and the drain area may be respectively disposed on both opposing sides of the gate electrode 135 while the channel area is disposed therebetween.

The interlayer insulating layer 140 is formed on the gate electrode 135. The interlayer insulating layer 140 may include the first contact hole 150 and the second contact hole 155 that expose the first portion 125a and the second portion 125b, respectively.

The first electrode 160 may be electrically connected to the first portion 125a of the active layer 125 while filling the first contact hole 150. In addition, the second electrode 165 may be electrically connected to the second portion 125b of the active layer 125 while filling the second contact hole 155.

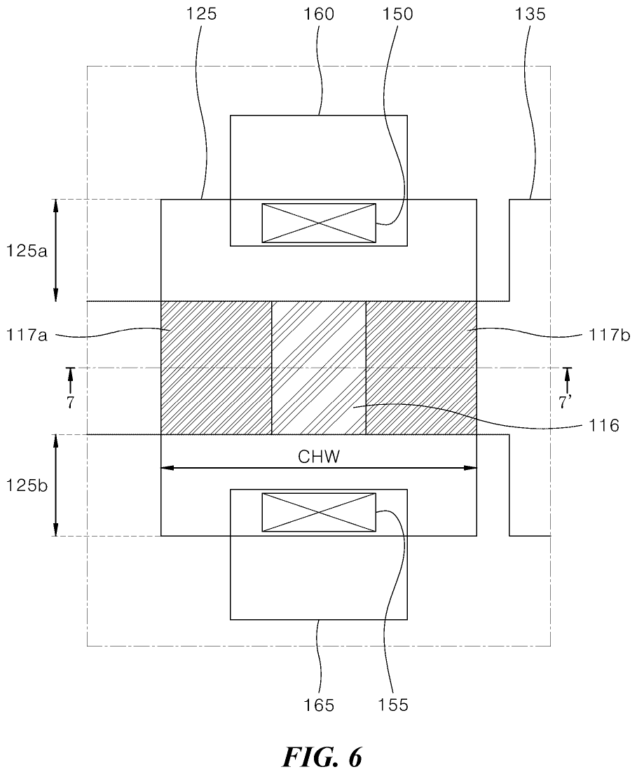

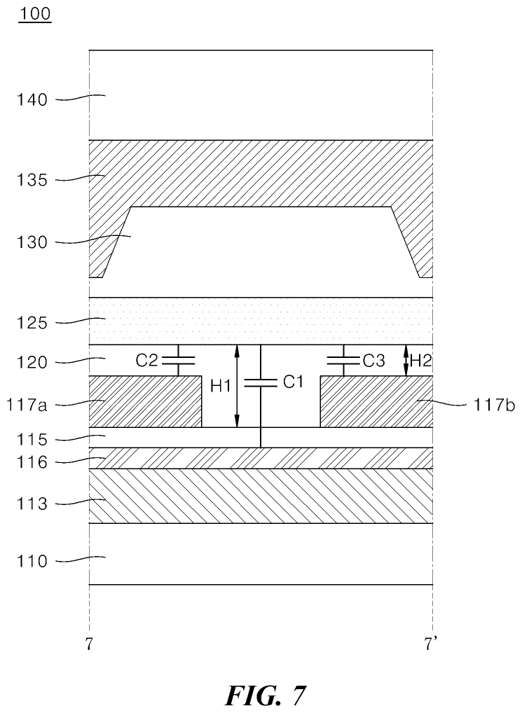

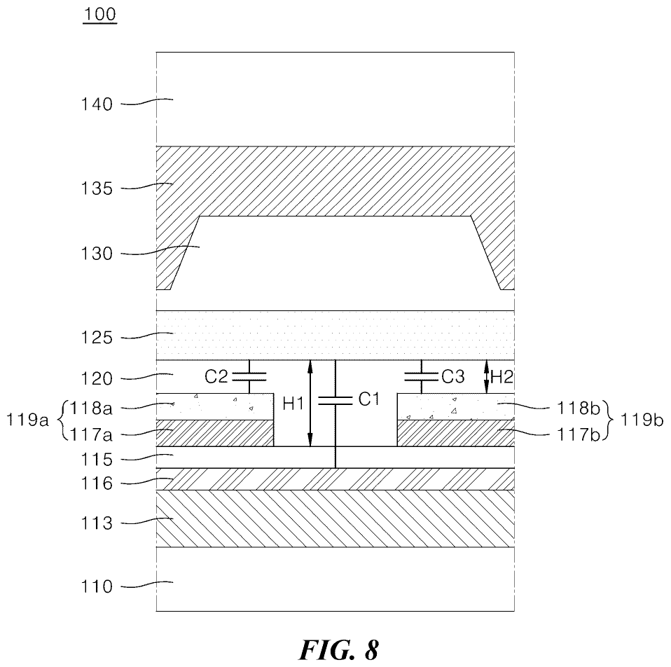

FIG. 6 is a plan view of a thin-film transistor according to another embodiment of the present disclosure. FIG. 7 is a cross-sectional view taken along a line 7-7′ of FIG. 6. FIG. 8 shows a variant example of a thin-film transistor according to another embodiment of the present disclosure. In FIG. 6 to FIG. 7, the same components as those of the thin-film transistor as described above with reference to FIG. 3 and FIG. 4 are given the same reference numerals, and the descriptions thereof are simplified or omitted.

Referring to FIG. 6 and FIG. 7, the light-blocking layer 113 may be disposed on the substrate 110. The light-blocking layer 113 may be positioned to overlap the active layer 125 vertically. The light-blocking layer 113 may protect the active layer 125 of the thin-film transistor 100 by blocking light incident from the outside. The light-blocking layer 113 may include an opaque metal material.

A semiconductor layer 116 may be disposed on the light-blocking layer 113. The semiconductor layer 116 may include a silicon-based semiconductor material. The semiconductor layer 116 may include amorphous silicon doped with a second conductive impurity. For example, the second conductive impurity may include a p-type impurity. The p-type impurity may include boron (B), indium (In), gallium (Ga), or aluminum (Al). In another example, the semiconductor layer 116 may include a semiconductor material that may be doped with the second conductive impurity.

The semiconductor layer 116 may be disposed to be in contact with one surface of the light-blocking layer 113 so as to increase a threshold voltage of the thin-film transistor 100.

Moreover, the semiconductor layer 116 may further absorb the ultraviolet rays the energy of which is corresponding to the band gap energy of a semiconductor material of the semiconductor layer 116. Accordingly, in this embodiment of the present disclosure, the light incident on the active layer 125 may be absorbed by the light-blocking layer 113 and the semiconductor layer 116, such that the reliability of the active layer 125 including the oxide semiconductor may be prevented from being deteriorated.

The first buffer layer 115 may be disposed on the semiconductor layer 116. The first buffer layer 115 may cover an upper surface of the semiconductor layer 116. The first buffer layer 115 may include silicon oxide (SiOₓ) or silicon nitride (SiNₓ). However, embodiments of the present disclosure are not limited thereto.

The first conductive pattern 117a may be disposed in the first area in the width CHW direction of the channel area and on the first buffer layer 115, while the second conductive pattern 117b may be disposed in the second area in the width CHW direction of the channel area and on the first buffer layer 115. Thus, the second conductive pattern 117b may be spaced apart from the first area. The area between the first conductive pattern 117a and the second conductive pattern 117b may be the third area.

Each of the first conductive pattern 117a and the second conductive pattern 117b may include an electrically conductive material.

The second buffer layer 120 may be disposed on the first conductive pattern 117a and the second conductive pattern 117b. The second buffer layer 120 may fill the space disposed in the third area and between the first conductive pattern 117a and the second conductive pattern 117b. In addition, the second buffer layer 120 may cover the upper surface of the first conductive pattern 117a in the first area of and the upper surface of the second conductive pattern 117b in the second area.

Accordingly, the second buffer layer 120 may have different thicknesses H1 and H2 in the first area, the second area, and the third area. For example, the second buffer layer 120 may have a first thickness H1 in the third area between the first conductive pattern 117a and the second conductive pattern 117b. In addition, the second buffer layer 120 may be formed on the first conductive pattern 117a to have the second thickness H2 in the first area and may be formed on the second conductive pattern 117b to have the second thickness H2 in the second area.

The active layer 125 may be disposed on the second buffer layer 120. The active layer 125 may include an oxide semiconductor material. Referring to FIG. 6, one side edge of the first conductive pattern 117a may be aligned with one side edge of the active layer 125. However, embodiments of the present disclosure are not limited thereto. The other side edge of the second conductive pattern 117b may be aligned with the other side edge of the active layer 125. However, embodiments of the present disclosure are not limited thereto.

The gate electrode 135 may be disposed on the active layer 125 while the gate insulating layer 130 is interposed therebetween. The gate electrode 135 may be positioned to overlap the active layer 125 in the vertical direction.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 penetrating through the interlayer insulating layer 140 and the gate insulating layer 130. The second electrode 165 may be electrically connected to the second area 125b of the active layer 125 via the second contact hole 150 penetrating through the interlayer insulating layer 140 and the gate insulating layer 130.

The thin-film transistor 100 may be composed of the active layer 125, the gate electrode 135, the first electrode 160, and the second electrode 165 formed in this manner.

According to another embodiment of the present disclosure, the thin-film transistor 100 may have a first capacitance C1 composed of the portion of the second buffer layer 120 having the first thickness H1 and the first buffer layer 115 disposed between the semiconductor layer 116 and the active layer 125 in the third area. The semiconductor layer 116 may be provided so as to be in contact with one surface of a light-blocking layer 113, so that the threshold voltage of the thin-film transistor 100 may be further increased.

In the first area, the portion of the second buffer layer 120 having the second thickness H2 may be disposed between the active layer 125 and the first conductive pattern 117a such that a second capacitance C2 may be formed. In addition, in the second area, the portion of the second buffer layer 120 having the second thickness H2 may be disposed between the active layer 125 and the second conductive pattern 117b such that a third capacitance C3 may be formed.

In this case, the first thickness HI of the portion of the second buffer layer 120 disposed in the space between the first conductive pattern 117a and the second conductive pattern 117b may be larger than the second thickness H2. The second thickness H2 of the portion of the second buffer layer 120 disposed between the active layer 125 and the second conductive pattern 117b in the second area may be equal to the second thickness H2 of the portion of the second buffer layer 120 disposed between the active layer 125 and the first conductive pattern 117a in the first area.

In addition, the first capacitance C1 may be formed between the semiconductor layer 116 and the active layer 125 based on a sum of a thickness of the first buffer layer 115 and the first thickness H1 of the second buffer layer 120. In this regard, the second capacitance C2 may be formed in the first area based on the second thickness H2 of the portion of the second buffer layer 120 that is smaller than in the first thickness H1 in the third area. Furthermore, the third capacitance C3 may be formed in the second area based on the second thickness H2 of the portion of the second buffer layer 120 that is smaller than in the first thickness H1 in the third area. Accordingly, a magnitude of the first capacitance C1 of the third area may be greater than a magnitude of each of the second capacitance C2 of the first area and the third capacitance C3 of the second area. The magnitude of the second capacitance C2 and the magnitude of the third capacitance C3 may be equal to each other.

Furthermore, the second capacitance C2 of the first area and the third capacitance C3 of the second area may be formed symmetrically with each other and may be respectively disposed on both opposing sides of the first capacitance C1 of the third area interposed therebetween. In the third area where the first capacitance C1 is formed, the threshold voltage may increase, while in each of the first area where the second capacitance C2 is formed and the second area where the third capacitance C3 is formed, the threshold voltage may be smaller compared to that in the third area. The portion of the second buffer layer 120 in the third area is thicker than the portion of the second buffer layer 120 in each of the first area and the second area, so that the driving current Ion may be the first magnitude of current in the third area. In addition, the portion of the second buffer layer 120 in each of the first area and the second area which is thinner than the portion of the second buffer layer 120 in the third area, so that the driving current Ion may have the second magnitude of current larger than the first magnitude of current in each of the first and second areas.

Accordingly, the driving current Ion of the thin-film transistor 100 may have a third magnitude of current as a sum of the first magnitude of current and the second magnitude of currents based on the current characteristics of the transistors connected in parallel with each other in the channel width CHW direction.

Therefore, while the driving current Ion may not be lowered, the S-factor may be controlled to have a high value. Thus, while the switching characteristics of the thin-film transistor may be maintained, low-gray level expression may be advantageously achieved. Furthermore, the semiconductor layer 116 may further absorb the ultraviolet rays the energy of which is corresponding to the band gap energy of a semiconductor material of the semiconductor layer 116. Accordingly, in this embodiment of the present disclosure, the light incident on the active layer 125 may be absorbed by the light-blocking layer 113 and the semiconductor layer 116, such that the reliability of the active layer 125 including the oxide semiconductor may be prevented from being deteriorated.

Referring to FIG. 8, the thin-film transistor 100 is different from that in FIG. 7 in that the first semiconductor pattern 118a and the second semiconductor pattern 118b are disposed on the upper surfaces of the first conductive pattern 117a and the second conductive pattern 117b, respectively.

The first semiconductor pattern 118a may be disposed on the first conductive pattern 117a to constitute the first conductive structure 119a on the first buffer layer 115. The second semiconductor pattern 118b may be disposed on the second conductive pattern 117b to constitute the second conductive structure 119b on the first buffer layer 115.

Since the first semiconductor pattern 118a and the second semiconductor pattern 118b are positioned so as to face the active layer 125, that is, so as to overlap each other, each of the first and second semiconductor patterns 118a and 118b may further absorb the ultraviolet rays the energy of which is corresponding to the band gap energy of a semiconductor material thereof. Accordingly, in this embodiment of the present disclosure, the external light which may be incident on the active layer 125 may be further absorbed by the light-blocking layer 113, the semiconductor layer 116, and the first and second semiconductor patterns 118a and 118b, thereby improving the reliability of the active layer 125.

Furthermore, in the third area, the second buffer layer 120 may be formed to have the first thickness H1, while in each of the first area and the second area, the second buffer layer 120 may be formed to have the second thickness H2.

Accordingly, in the third area, the first capacitance C1 may be formed, while in the first area and the second area, the second capacitance C2 and the third capacitance C3 which are different from the first capacitance C1, may be formed, respectively.

In the third area where the first capacitance C1 is formed, the threshold voltage may increase, while in each of the first area where the second capacitance C2 is formed and the second area where the third capacitance C3 is formed, the threshold voltages may be relatively reduced. Furthermore, the second capacitance C2 of the first area and the third capacitance C3 of the second area of one thin-film transistor 100 may be formed symmetrically with each other around the first capacitance C1 of the third area interposed therebetween.

The third magnitude of current which is the sum of the first magnitude of current of the first area and the second area and the second magnitude of current of the third area may be generated as the driving current Ion of the thin-film transistor. Accordingly, the driving current Ion may be prevented from decreasing.

Therefore, while the driving current Ion may not be lowered, the S-factor may be controlled to have a high value. Thus, while the switching characteristics of the thin-film transistor may be maintained, low-gray level expression may be advantageously achieved.

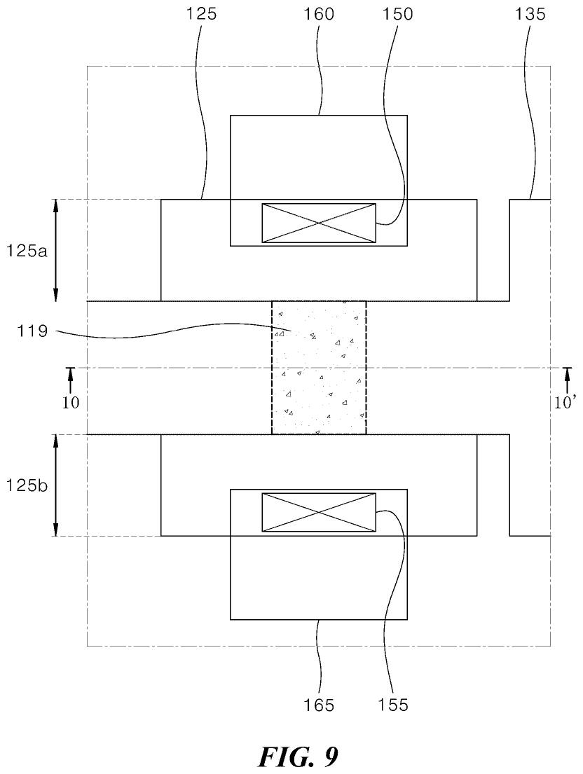

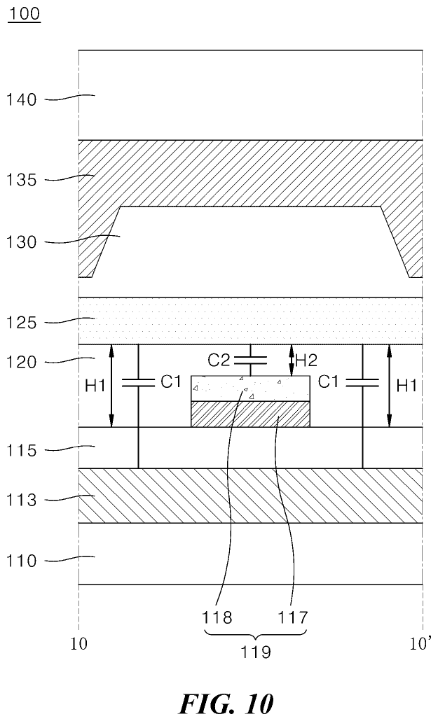

FIG. 9 is a plan view of a thin-film transistor according to still another embodiment of the present disclosure. FIG. 10 is a cross-sectional view taken along a line 10-10′ of FIG. 9. In FIGS. 9 and 10, the same components as those of the thin-film transistor described above with reference to FIGS. 3 and 4 are given the same reference numerals, and the descriptions thereof are simplified or omitted.

Referring to FIG. 9 and FIG. 10, a light-blocking layer 113 may be disposed on a substrate 110.

The light-blocking layer 113 may be positioned to overlap the active layer 125 in the vertical direction. The light-blocking layer 113 may block light incident thereto from an outside. The active layer 125 of the thin-film transistor 100 may be protected by the light-blocking layer 113. To this end, the light-blocking layer 113 may include a material that is electrically conductive and may block light incident thereto from the outside. For example, the light-blocking layer 113 may be formed as a single layer or a stack of multiple layers made of one or more opaque metal materials selected from the group of molybdenum (Mo), aluminum (Al), titanium (Ti), and copper (Cu), and an alloy thereof. However, the present disclosure is not limited thereto. The light-blocking layer 113 may include an opaque metal material.

The first buffer layer 115 may be disposed on the light-blocking layer 113. The first buffer layer 115 may cover the entire upper surface of the light-blocking layer 113. The first buffer layer 115 may include, but is not limited to, silicon oxide (SiOₓ) or silicon nitride (SiNₓ).

A conductive structure 119 may be disposed on the first buffer layer 115. The conductive structure 119 may include a conductive pattern 117 and a semiconductor pattern 118. For example, the conductive structure 119 may be a structure in which the conductive pattern 117 and the semiconductor pattern 118 are arranged or stacked vertically.

The conductive structure 119 may be positioned in an area overlapping a center portion of an entire area of the active layer 125. However, the present disclosure is not limited thereto. The area in which the conductive structure 119 is disposed may be referred to as the first area.

One side area around the conductive structure 119 may be referred to as the second area. Furthermore, the other side area around the conductive structure 119 and opposite to the second area may be referred to as the third area.

The conductive pattern 117 may include a material having electrical conductivity. For example, the conductive pattern 117 may be formed as a single layer or a stack of multiple layers made of one or more selected from a group of opaque metal materials such as molybdenum (Mo), aluminum (Al), titanium (Ti), and copper (Cu), and an alloy thereof. However, embodiments of the present disclosure are not limited to these materials.

The semiconductor pattern 118 disposed on the conductive pattern 117 may include a silicon-based semiconductor material. The semiconductor pattern 118 may include amorphous silicon including a first conductive impurity. For example, the first conductive impurity may include an n-type impurity. The n-type impurity may include phosphorus (P), arsenic (As), or antimony (Sb). In another example, the semiconductor pattern 118 may include a semiconductor material doped with the first conductive impurity.

The second buffer layer 120 may be disposed on the first buffer layer 115 and the conductive structure 119. Each portion of the second buffer layer 120 having a first thickness H1 may be in contact with each of both opposing exposed portions of the upper surface of the first buffer layer 115. A portion of the second buffer layer 120 may be formed on the upper surface of the conductive structure 119 so as to have a second thickness H2. Accordingly, in each of the second area and the third area disposed on both opposing sides of the conductive structure 119, respectively, the portion of the second buffer layer 120 may be formed to have the first thickness H1 larger than the second thickness H2.

The active layer 125 may be disposed on the second buffer layer 120. The active layer 125 may include an oxide semiconductor material.

The gate electrode 135 may be disposed on the active layer 125 while the gate insulating layer 130 is interposed therebetween. The gate electrode 135 may be positioned to overlap the active layer 125 in the vertical direction.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 penetrating through the interlayer insulating layer 140 and the gate insulating layer 130. The second electrode 165 may be electrically connected to the second area 125b of the active layer 125 via the second contact hole 150 penetrating through the interlayer insulating layer 140 and the gate insulating layer 130.

A thin-film transistor 100 may be composed of the active layer 125, the gate electrode 135, the first electrode 160, and the second electrode 165 formed in this manner.

According to still another embodiment of the present disclosure, the portion of the second buffer layer 120 having the second thickness H2 may be disposed between the active layer 125 and the conductive structure 119 in the first area, so that a second capacitance C2 may be formed in the first area. In addition, the portion of the second buffer layer 120 and the first buffer layer 115 may be disposed between the light-blocking layer 113 and the active layer 125 in each of the second area and the third area which are symmetrically arranged with each other around the conductive structure 119, so that a first capacitance C1 may be formed in each of the second area and the third area.

The first thickness H1 of the second buffer layer 120 may be larger than the second thickness H2. Accordingly, the first capacitance C1 of each of the second area and the third area may have a magnitude larger than a magnitude of the second capacitance C2.

In the first area where the second buffer layer 120 with a relatively smaller second thickness H2 is disposed, a relatively lower threshold voltage may be generated, so that the driving current Ion may increase, and thus, the first area may have a first magnitude of current. Each of the second area and the third area where the second buffer layer having the first thickness H1 larger than the second thickness H2 may have a relatively high threshold voltage, so that the driving current Ion in each of the second and third areas may be reduced and thus each of the second and third areas may have a second magnitude of current.

Due to the operating characteristics of the parallel-connected transistors, the total magnitude of current of the driving current of the thin-film transistor may be generated as the third magnitude of current as the sum of the first magnitude of current and the second magnitude of currents. Accordingly, the driving current in each of the second area and the third area where the driving current Ion is relatively reduced may be prevented from being reduced.

Therefore, while the driving current Ion may not be lowered, the S-factor may be controlled to have a high value. Thus, while the switching characteristics of the thin-film transistor may be maintained, low-gray level expression may be advantageously achieved.

Moreover, the semiconductor pattern 118 may further absorb the ultraviolet rays the energy of which is corresponding to the band gap energy of a semiconductor material thereof. Accordingly, in this embodiment of the present disclosure, the light incident on the active layer 125 may be absorbed by the light-blocking layer 113 and the semiconductor pattern 118, such that the reliability of the active layer 125 including the oxide semiconductor may be prevented from being deteriorated.

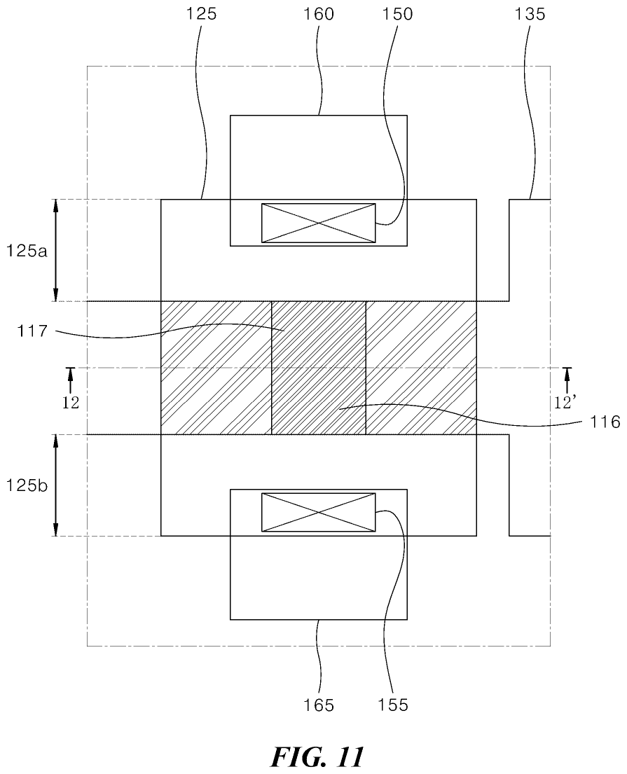

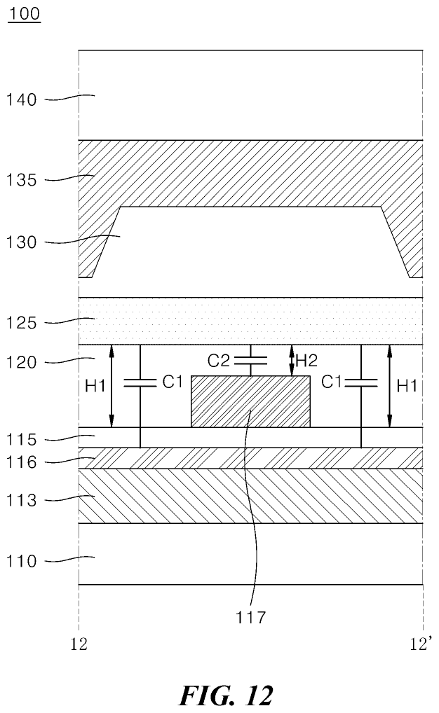

FIG. 11 is a plan view of a thin-film transistor according to still yet another embodiment of the present disclosure. FIG. 12 is a cross-sectional view taken along a line 12-12′ of FIG. 11. In FIG. 11 and FIG. 12, the same components as those of the thin-film transistor as described above with reference to FIG. 6 and FIG. 7 are given the same reference numerals, and the descriptions thereof are simplified or omitted.

Referring to FIG. 11 and FIG. 12, the thin-film transistor according to still yet another embodiment of the present disclosure may have the semiconductor layer 116 in contact with the upper surface of the light-blocking layer 113. In addition, the conductive pattern 117 may be disposed in an area overlapping the center portion of the entire area of the active layer 125. However, the present disclosure is not limited thereto.

The area where the conductive pattern 117 is disposed may be referred to as a first area. One side area around the conductive pattern 117 may be referred to as a second area. Furthermore, the other side area around the conductive pattern 117 and opposite to the second portion may be referred to as a third area.

The second buffer layer 120 may be disposed on the upper surface of the first buffer layer 115 except for a portion on which the conductive pattern 117 is disposed. Further, the second buffer layer 120 may be disposed on an upper surface of the conductive pattern 117. The portion of the upper surface of the first buffer layer 115 on which the conductive pattern 117 is disposed may be the first area. In each of the second area and the third area in which the second buffer layer 120 is disposed on and in contact with the first buffer layer 115, a portion of the second buffer layer 120 may be formed to have a first thickness H1. The first area is positioned between the second and third areas.

In the first area where the conductive pattern 117 is disposed, a portion of the second buffer layer 120 may be formed to have a second thickness H2. Accordingly, a second capacitance C2 may be formed in the first area. In each of the second area and the third area, which are symmetrically arranged with each other around the first area interposed therebetween, a first capacitance C1 may be formed.

The first capacitance C1 may have a magnitude greater than that of the second capacitance C2.

In the first area where the second buffer layer 120 is arranged with a relatively thin second thickness H2, a relatively small threshold voltage is generated, so that the driving current Ion increases and may be generated as the first magnitude of current. In each of the second area and the third area which are symmetrically arranged with each other around the first area interposed therebetween, the semiconductor layer 116, the first buffer layer 115, and the second buffer layer 120 are stacked vertically, so that a relatively higher threshold voltage may be generated, so that the driving current Ion decreases and may be generated as a second magnitude of current.

Due to the operating characteristics of the parallel-connected transistors, the total magnitude of current of the driving current of the thin-film transistor may be generated as the third magnitude of current as the sum of the first magnitude of current and the second magnitude of currents. Accordingly, the driving current in each of the second area and the third area where the driving current Ion is relatively reduced may be prevented from being reduced.

Therefore, while the driving current Ion may not be lowered, the S-factor may be controlled to have a high value. Thus, while the switching characteristics of the thin-film transistor may be maintained, low-gray level expression may be advantageously achieved.

Moreover, the semiconductor layer 116 may further absorb the ultraviolet rays the energy of which is corresponding to the band gap energy of a semiconductor material of the semiconductor layer 116. Accordingly, in this embodiment of the present disclosure, the light incident on the active layer 125 may be absorbed by the light-blocking layer 113 and the semiconductor layer 116, such that the reliability of the active layer 125 including the oxide semiconductor may be prevented from being deteriorated.

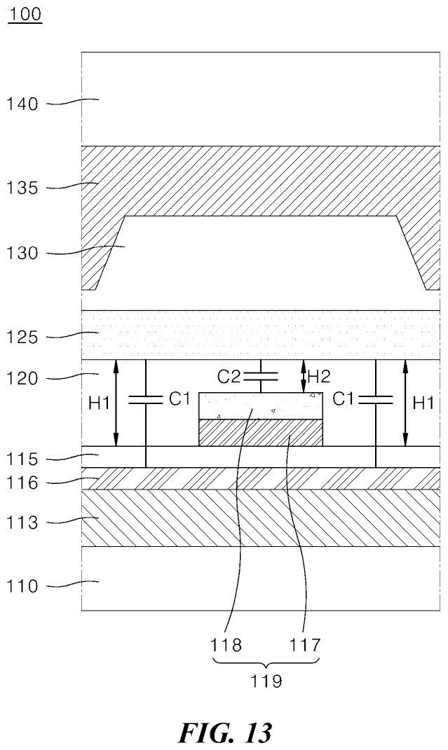

FIG. 13 is a variant example of a thin-film transistor according to still yet another embodiment of the present disclosure. In FIG. 13, the same components as those of the thin-film transistor described above with reference to FIG. 11 and FIG. 12 are given the same reference numerals, and the descriptions thereof are simplified or omitted.

Referring to FIG. 13, a variant example of a thin-film transistor according to still yet another embodiment of the present disclosure may have the conductive structure 119 disposed in an area overlapping the center portion of the entire area of the active layer 125. The area where the conductive structure 119 is disposed may be referred to as a first area. One side area around the conductive structure 119 may be referred to as the second area. Furthermore, the other side area around the conductive structure 119 and opposite to the second area may be referred to as the third area.

The conductive structure 119 may include the conductive pattern 117 and the semiconductor pattern 118. For example, the conductive structure 119 may be a structure in which the conductive pattern 117 and the semiconductor pattern 118 are stacked vertically.

The second buffer layer 120 may be disposed on the first buffer layer 115 and the conductive structure 119. Each portion of the second buffer layer 120 having a first thickness H1 may be in contact with each of both opposing exposed portions of the upper surface of the first buffer layer 115. A portion of the second buffer layer 120 may be formed on the upper surface of the conductive structure 119 so as to have a second thickness H2. Accordingly, in each of the second area and the third area disposed on both opposing sides of the conductive structure 119, respectively, the portion of the second buffer layer 120 may be formed to have the first thickness H1 larger than the second thickness H2.

The portion of the second buffer layer 120 having the second thickness H2 may be disposed between the active layer 125 and the conductive structure 119 in the first area, so that a second capacitance C2 may be formed in the first area. In addition, the portion of the second buffer layer 120 and the first buffer layer 115 may be disposed between the semiconductor layer 116 and the active layer 125 in each of the second area and the third area which are symmetrically arranged with each other around the conductive structure 119, so that a first capacitance C1 may be formed in each of the second area and the third area.

The first thickness H1 of the second buffer layer 120 may be larger than the second thickness H2. Accordingly, the first capacitance C1 of each of the second area and the third area may have a magnitude larger than a magnitude of the second capacitance C2.

In the first area where the second buffer layer 120 with a relatively smaller second thickness H2 is disposed, a relatively lower threshold voltage may be generated, so that the driving current Ion may increase, and thus, the first area may have a first magnitude of current. Each of the second area and the third area where the second buffer layer having the first thickness H1 larger than the second thickness H2 may have a relatively high threshold voltage, so that the driving current Ion in each of the second and third areas may be reduced and thus each of the second and third areas may have a second magnitude of current.

Due to the operating characteristics of the parallel-connected transistors, the total magnitude of current of the driving current of the thin-film transistor may be generated as the third magnitude of current as the sum of the first magnitude of current and the second magnitude of currents. Accordingly, the driving current in each of the second area and the third area where the driving current Ion is relatively reduced may be prevented from being reduced.

Therefore, while the driving current Ion may not be lowered, the S-factor may be controlled to have a high value. Thus, while the switching characteristics of the thin-film transistor may be maintained, low-gray level expression may be advantageously achieved.

Moreover, the semiconductor pattern 118 may further absorb the ultraviolet rays the energy of which is corresponding to the band gap of energy of a semiconductor material thereof. Accordingly, in this embodiment of the present disclosure, the light incident on the active layer 125 may be absorbed by the light-blocking layer 113 and the semiconductor pattern 118, such that the reliability of the active layer 125 including the oxide semiconductor may be prevented from being deteriorated.

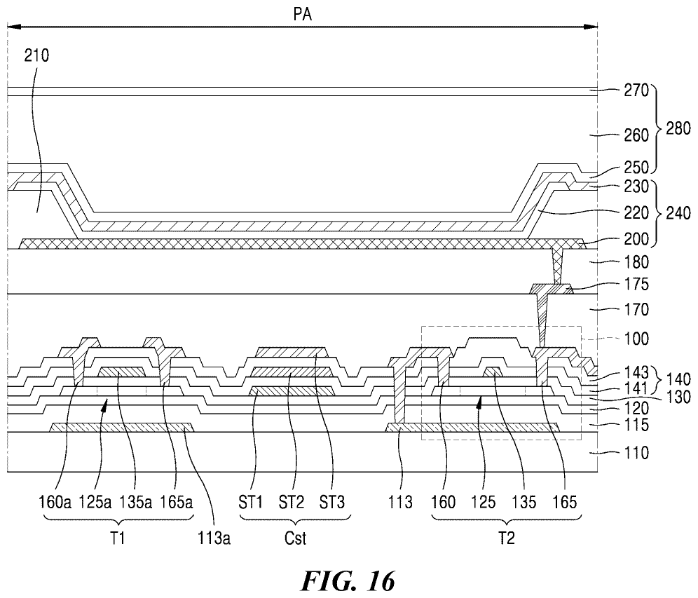

FIG. 16 is a cross-sectional view showing one of pixel areas of a display apparatus including a thin-film transistor according to some embodiments of the present disclosure in an enlarged manner. An example in which the display apparatus is embodied as an organic light-emitting diode display apparatus is described below. However, embodiments of the present disclosure are not limited thereto.

Referring to FIG. 16, a first thin-film transistor T1, a second thin-film transistor T2, and a storage capacitor Cst may be disposed on a substrate 110 and in a pixel area PA. For example, the second thin-film transistor T2 may include at least one thin-film transistor 100 among the thin-film transistors as described in FIGS. 3 to 13 of the present disclosure.

The first thin-film transistor T1 may be, for example, a switching transistor. The second thin-film transistor T2 may be, for example, a driving thin-film transistor.

The light-blocking layer 113 and a first light-blocking layer 113a may be disposed on the substrate 110. The light-blocking layer 113 may be disposed under the first thin-film transistor T1, and the first light-blocking layer 113a may be positioned at a different position from a position of the light-blocking layer 113.

The first light-blocking layer 113a may be disposed under the second thin-film transistor T2.

The first buffer layer 115 may be disposed on the light-blocking layer 113 and the first light-blocking layer 113a. In one example, one of the structures as described in FIG. 3 to FIG. 13 according to some embodiments of the present disclosure may be disposed between the light-blocking layer 113 and the first buffer layer 115. For example, one of the structures as described in FIG. 3 to FIG. 13 may be disposed between the first buffer layer 115 and the second buffer layer 120 according to embodiments of the present disclosure.

The active layer 125 may be disposed on the second buffer layer 120. A first active layer 125a may be positioned at a different location from a position of the active layer 125. The gate insulating layer 130 may be disposed on the active layer 125 and the first active layer 125a. The gate electrode 135 may be disposed on the gate insulating layer 130. The gate electrode 135 may be positioned to overlap the active layer 125 in a vertical direction. The first gate electrode 135a may be positioned at a different location from that of the gate electrode 135.

The interlayer insulating layer 140 may be disposed on the gate electrode 135 and the first gate electrode 135a. For example, the interlayer insulating layer 140 may include a multilayer including a first interlayer insulating layer 141 and a second interlayer insulating layer 143. However, embodiments of the present disclosure are not limited thereto.

The first electrode 160 and the second electrode 165 may be disposed on the interlayer insulating layer 140. The first electrode 160 may penetrate through the interlayer insulating layer 140 and the gate insulating layer 130 so as to be electrically connected to one side of the active layer 125. Furthermore, the second electrode 165 may penetrate through the interlayer insulating layer 140 and the gate insulating layer 130 so as to be electrically connected to the other side of the active layer 125. At locations different from the positions of the first electrode 160 and the second electrode 165, a first electrode 160a of the first thin-film transistor T1 and a second electrode 165a of the first thin-film transistor T1 may be positioned. Each of the first electrode 160a of the first thin-film transistor T1 and the second electrode 165a of the first thin-film transistor T1 may be electrically connected to the first active layer 125a.

The second thin-film transistor T2 may include the active layer 125, the gate electrode 135, the first electrode 160, and the second electrode 165. The first thin-film transistor T1 may include the first active layer 125a, the first gate electrode 135a, the first electrode 160a, and the second electrode 165a.

The storage capacitor Cst of each pixel area PA may include a stack structure of capacitor electrodes ST1, ST2, and ST3. The storage capacitor Cst may include a first capacitor electrode ST1, a second capacitor electrode ST2, and a third capacitor electrode ST3. The storage capacitor Cst may be formed within a corresponding pixel area PA in a process of forming the first thin-film transistor T1 and the second thin-film transistor T2. For example, the first capacitor electrode ST1 and the gate electrode 135 may be disposed on the same layer. The second capacitor electrode ST2 may be disposed on the first interlayer insulating layer 141. The third capacitor electrode ST3 and the second electrode 165 may be disposed on the same layer. Accordingly, an area occupied with the storage capacitor Cst within each pixel area PA may be minimized.

A first planarization layer 170 may be disposed on the interlayer insulating layer 140, the first electrode 160, and the second electrode 165. The first planarization layer 170 may planarize a step caused by the underlying circuit elements such as the first thin-film transistor T1, the second thin-film transistor T2, and the storage capacitor Cst. The first planarization layer 170 may include an organic insulating material such as acryl. However, embodiments of the present disclosure are not limited thereto.

A connection electrode 175 may be disposed on the first planarization layer 170. The connection electrode 175 may be electrically connected to the second electrode 165 of the second thin-film transistor T2 via a contact hole penetrating through the first planarization layer 170. However, the present disclosure is not limited thereto. In another example, the connecting electrode 175 may be electrically connected to the first electrode 160 of the second thin-film transistor T2. A second planarization layer 180 may be disposed on the first planarization layer 170.

A light-emitting element 240 may be disposed on the second flattening layer 180. The light-emitting element 240 may include an anode electrode 200, a light-emitting layer 220, and a cathode electrode 230. In this regard, the anode electrode 200 may be referred to as a pixel electrode, and the cathode electrode 230 may be referred to as a counter electrode. However, the present disclosure is not limited to these terms. The light-emitting element 240 of the present disclosure may be embodied as an organic light-emitting diode element. However, embodiments of the present disclosure are not limited thereto, and various types of light-emitting elements may be used.

The anode electrode 200 may be disposed on the second flattening layer 180. One surface of the anode electrode 200 may be in contact with an upper surface of the connection electrode 175. Accordingly, the anode electrode 200 may be electrically connected to the thin-film transistor 100 via the connection electrode 175 and the first electrode 160.

The anode electrode 200 may include a metal oxide such as indium tin oxide (ITO) or indium zinc oxide (IZO). However, embodiments of the present disclosure are not limited thereto. Alternatively, the anode electrode 200 may include a single-layer or a multi-layer structure including a reflective metal film made of silver (Ag), aluminum (Al), gold (Au), nickel (Ni), chromium (Cr), and an alloy thereof.

A bank 210 may be disposed on the second planarization layer 180. The bank 210 may distinguish neighboring pixels from each other. For this purpose, the bank 210 may be formed to cover an edge of the anode electrode 200. Furthermore, the bank 210 may prevent different colors of different light beams output from adjacent pixels from being mixed with each other. The bank 210 may include an organic insulating film made of, for example, polyimide or epoxy. However, embodiments of the present disclosure are not limited thereto.

The light-emitting layer 220 may be disposed on the anode electrode 200. In one example, the light-emitting layer 220 may include an organic material that emits each of light beams of different colors in different pixels. For example, the light-emitting layer 220 may emit light of one color among red, green, blue, and white. In another example, the light-emitting layer 220 may be made of an organic material that emits white light, and light of one color among red, green, or blue may be generated using a color filter.

The cathode electrode 230 may be disposed on the light-emitting layer 220. The cathode electrode 230 may be formed to cover the light-emitting layer 220. The cathode electrode 230 may be commonly formed across a plurality of pixels. The cathode electrode 230 may include a metal oxide such as indium tin oxide (ITO) or indium zinc oxide (IZO). However, embodiments of the present disclosure are not limited thereto. Alternatively, the cathode electrode 230 may include a single-layer or a multi-layer structure including a reflective metal film made of silver (Ag), aluminum (Al), gold (Au), nickel (Ni), chromium (Cr), and an alloy thereof.

An encapsulation portion 280 may be disposed on the cathode electrode 230. The encapsulation part 280 may include a first encapsulation layer 250, a second encapsulation layer 260, and a third encapsulation layer 270.

The first encapsulation layer 250 may be disposed on the cathode electrode 230. The first encapsulation layer 250 may include an inorganic insulating material. For example, the first encapsulation layer 250 may include at least one inorganic insulating material among silicon nitride (SiNₓ), silicon oxide (SiOₓ), and silicon oxynitride (SiON).

The second encapsulation layer 260 may cover the first encapsulation layer 250 and have a sufficient thickness so as to have a flat upper surface. The second encapsulation layer 260 may prevent foreign substances from invading into the light-emitting element 240. The second encapsulation layer 260 may include an organic insulating material. For example, the second encapsulation layer 260 may include at least one material selected from epoxy, polyimide, polyethylene, or acrylate.

The third encapsulation layer 270 may be disposed on the second encapsulation layer 260. The third encapsulation layer 270 may include an inorganic insulating material. For example, the third encapsulation layer 255 may include at least one inorganic insulating material among silicon nitride (SiNₓ), silicon oxide (SiOₓ), and silicon oxynitride (SiON).

A display apparatus according to various embodiments of the present disclosure may be described as follows.

A first aspect of the present disclosure provides a thin-film transistor comprising: a substrate; a light-blocking layer disposed on the substrate; a first buffer layer disposed on the light-blocking layer; an active layer disposed on the first buffer layer; a gate electrode disposed on the active layer; at least one conductive structure disposed between the light-blocking layer and the active layer; and a second buffer layer disposed between the light-blocking layer and the active layer so as to cover the conductive structure.

In accordance with some embodiments of the thin-film transistor of the first aspect, the conductive structure includes at least one semiconductor pattern overlapping the active layer in a vertical direction, wherein the at least one semiconductor pattern includes: a first semiconductor pattern overlapping a first area of the active layer; and a second semiconductor pattern overlapping a second area of the active layer, wherein the second area is spaced apart from the first area, wherein the first buffer layer is not covered with the conductive structure in a third area between the first area and the second area.

In accordance with some embodiments of the thin-film transistor of the first aspect, the first semiconductor pattern and the second semiconductor pattern are arranged so as to be spaced apart from each other in a first direction of the active layer, wherein the first direction is a width direction of the channel area.

In accordance with some embodiments of the thin-film transistor of the first aspect, the first semiconductor pattern or the second semiconductor pattern includes a semiconductor material doped with a first conductive impurity.

In accordance with some embodiments of the thin-film transistor of the first aspect, the semiconductor material includes amorphous silicon.

In accordance with some embodiments of the thin-film transistor of the first aspect, the first conductive impurity includes an n-type impurity including phosphorus (P), arsenic (As), or antimony (Sb).

In accordance with some embodiments of the thin-film transistor of the first aspect, the conductive structure further includes: a first conductive pattern disposed under the first semiconductor pattern; and a second conductive pattern disposed under the second semiconductor pattern, wherein each of the first conductive pattern and the second conductive pattern is disposed on the light-blocking layer while the first buffer layer is disposed between each of the first conductive pattern and the second conductive pattern and the light-blocking layer.

In accordance with some embodiments of the thin-film transistor of the first aspect, a portion of the second buffer layer disposed on the first buffer layer in the third area has a first thickness, wherein a portion of the second buffer layer disposed on the first semiconductor pattern in the first area has a second thickness, wherein a portion of the second buffer layer disposed on the second semiconductor pattern in the second area has the second thickness, wherein the first thickness is greater than the second thickness.

In accordance with some embodiments of the thin-film transistor of the first aspect, the thin-film transistor further comprises a semiconductor layer disposed between the light-blocking layer and the first buffer layer.

In accordance with some embodiments of the thin-film transistor of the first aspect, the semiconductor layer includes a semiconductor material doped with a second conductive impurity different from the first conductive impurity.

In accordance with some embodiments of the thin-film transistor of the first aspect, the second conductive impurity includes a p-type impurity including boron (B), indium (In), gallium (Ga) or aluminum (Al).

In accordance with some embodiments of the thin-film transistor of the first aspect, the active layer includes a first area, a second area spaced apart from the first area in a first direction, and a third area between the first area and the second area, wherein the conductive structure includes a semiconductor pattern overlapping the third area of the active layer, wherein the first direction is a width direction of the channel area.

In accordance with some embodiments of the thin-film transistor of the first aspect, the semiconductor pattern includes a semiconductor material doped with a first conductive impurity, wherein the first conductive impurity includes an n-type impurity.

In accordance with some embodiments of the thin-film transistor of the first aspect, the conductive structure further includes a conductive pattern disposed under the semiconductor pattern, wherein the conductive pattern is disposed on the light-blocking layer while the first buffer layer is interposed between the conductive pattern and the light-blocking layer.

In accordance with some embodiments of the thin-film transistor of the first aspect, a portion of the second buffer layer overlapping the third area has a first thickness, wherein a portion of the second buffer layer overlapping each of the first and second areas has a second thickness, wherein the first thickness is smaller than the second thickness.

In accordance with some embodiments of the thin-film transistor of the first aspect, the thin-film transistor further comprises a semiconductor layer disposed between the light-blocking layer and the first buffer layer.

In accordance with some embodiments of the thin-film transistor of the first aspect, the semiconductor layer includes a semiconductor material doped with a second conductive impurity different from the first conductive impurity, wherein the second conductive impurity includes a p-type impurity.

In accordance with some embodiments of the thin-film transistor of the first aspect, the conductive structure includes at least one conductive pattern overlapping the active layer, wherein the at least one conductive pattern includes: a first conductive pattern overlapping the first area of the active layer; and a second conductive pattern overlapping a second area of the active layer, wherein the second area is spaced apart from the first area, wherein the first buffer layer is not covered with the conductive structure in a third area defined between the first area and the second area.

In accordance with some embodiments of the thin-film transistor of the first aspect, the thin-film transistor further comprises a semiconductor layer disposed between the light-blocking layer and the first buffer layer, wherein the semiconductor layer includes a semiconductor material doped with a p-type impurity.

In accordance with some embodiments of the thin-film transistor of the first aspect, the active layer includes a first area, a second area spaced apart from the first area in a first direction, and a third area between the first area and the second area, wherein the conductive structure includes a conductive pattern overlapping the third area of the active layer, wherein the first direction is a width direction of the channel area.

In accordance with some embodiments of the thin-film transistor of the first aspect, the thin-film transistor further comprises a semiconductor layer disposed between the light-blocking layer and the first buffer layer, wherein the semiconductor layer includes a semiconductor material doped with a p-type impurity.

A second aspect of the present disclosure provides a display apparatus comprising: a light-emitting element; and a thin-film transistor connected to the light-emitting element, wherein the thin-film transistor includes the thin-film transistor of the first aspect.

In accordance with some embodiments of the display apparatus of the second aspect, the light-emitting element includes: a first electrode connected to the thin-film transistor; a light-emitting layer disposed on the first electrode; and a second electrode disposed on the light-emitting layer.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin-film transistor comprising:
a substrate;
a light-blocking layer on the substrate;
a first buffer layer on the light-blocking layer;
an active layer on the first buffer layer;
a gate electrode on the active layer;
at least one conductive structure between the first buffer layer and the active layer; and
a second buffer layer disposed the first buffer layer and the active layer, the second buffer layer covering the conductive structure.

2. The thin-film transistor of claim 1, wherein each of the at least one conductive structure includes a semiconductor pattern overlapping the active layer in a vertical direction,
wherein the at least one semiconductor pattern includes:
a first conductive structure including a first semiconductor pattern on a first area of the first buffer layer; and
a second conductive structure including a second semiconductor pattern on a second area of the first buffer layer,
wherein the second area is spaced apart from the first area,
wherein an area of the first buffer layer except the first area and the second area is a third area.

3. The thin-film transistor of claim 2, wherein the first semiconductor pattern and the second semiconductor pattern are spaced apart from each other in a first direction of the active layer, and
wherein the first direction is a width direction of a channel area.

4. The thin-film transistor of claim 2, wherein either the first semiconductor pattern or the second semiconductor pattern includes a semiconductor material doped with a first conductive impurity.

5. The thin-film transistor of claim 4, wherein the semiconductor material includes amorphous silicon.

6. The thin-film transistor of claim 4, wherein the first conductive impurity includes an n-type impurity including phosphorus (P), arsenic (As), or antimony (Sb).

7. The thin-film transistor of claim 2, wherein:
the first conductive structure further includes a first conductive pattern adjacent to the first semiconductor pattern; and
the second conductive structure further includes a second conductive pattern adjacent to the second semiconductor pattern,
wherein each of the first conductive pattern and the second conductive pattern is on the light-blocking layer while the first buffer layer is disposed between each of the first conductive pattern and the second conductive pattern and the light-blocking layer.

8. The thin-film transistor of claim 2, wherein a portion of the second buffer layer on the first buffer layer in the third area has a first thickness,
wherein a portion of the second buffer layer on the first semiconductor pattern in the first area has a second thickness,
wherein a portion of the second buffer layer on the second semiconductor pattern in the second area has the second thickness, and
wherein the first thickness is greater than the second thickness.

9. The thin-film transistor of claim 4, wherein the thin-film transistor further comprises a semiconductor layer between the light-blocking layer and the first buffer layer.

10. The thin-film transistor of claim 9, wherein the semiconductor layer includes a semiconductor material doped with a second conductive impurity different from the first conductive impurity.

11. The thin-film transistor of claim 10, wherein the second conductive impurity includes a p-type impurity including boron (B), indium (In), gallium (Ga) or aluminum (Al).

12. The thin-film transistor of claim 1, wherein the active layer includes a first area, a second area spaced apart from the first area in a first direction, and a third area between the first area and the second area,
wherein the conductive structure includes a semiconductor pattern overlapping the third area of the active layer, and
wherein the first direction is a width direction of the channel area.

13. The thin-film transistor of claim 12, wherein the semiconductor pattern includes a semiconductor material doped with a first conductive impurity, and
wherein the first conductive impurity includes an n-type impurity.

14. The thin-film transistor of claim 12, wherein the conductive structure further includes a conductive pattern adjacent to the semiconductor pattern, and
wherein the conductive pattern is on the light-blocking layer while the first buffer layer is interposed between the conductive pattern and the light-blocking layer.

15. The thin-film transistor of claim 12, wherein a portion of the second buffer layer overlapping the third area has a first thickness,
wherein a portion of the second buffer layer overlapping each of the first and second areas has a second thickness, and
wherein the first thickness is smaller than the second thickness.

16. The thin-film transistor of claim 13, wherein the thin-film transistor further comprises a semiconductor layer disposed between the light-blocking layer and the first buffer layer.

17. The thin-film transistor of claim 16, wherein the semiconductor layer includes a semiconductor material doped with a second conductive impurity different from the first conductive impurity, and
wherein the second conductive impurity includes a p-type impurity.

18. The thin-film transistor of claim 1, wherein each of the at least one conductive structure includes at least one conductive pattern overlapping the active layer,
wherein the at least one conductive pattern includes:
a first conductive structure including a first conductive pattern overlapping the first area of the active layer; and
a second conductive structure including a second conductive pattern overlapping a second area of the active layer,
wherein the second area is spaced apart from the first area,
wherein the first buffer layer is not covered with the conductive structure in a third area defined between the first area and the second area.

19. The thin-film transistor of claim 18, wherein the thin-film transistor further comprises a semiconductor layer between the light-blocking layer and the first buffer layer, and
wherein the semiconductor layer includes a semiconductor material doped with a p-type impurity.

20. The thin-film transistor of claim 1, wherein the active layer includes a first area, a second area spaced apart from the first area in a first direction, and a third area between the first area and the second area,
wherein the conductive structure includes a conductive pattern overlapping the third area of the active layer, and
wherein the first direction is a width direction of the channel area.

21. The thin-film transistor of claim 20, wherein the thin-film transistor further comprises a semiconductor layer between the light-blocking layer and the first buffer layer, and
wherein the semiconductor layer includes a semiconductor material doped with a p-type impurity.

22. A display apparatus comprising:
a light-emitting element; and
a thin-film transistor electrically connected to the light-emitting element, the thin-film transistor including:
a substrate;
a light-blocking layer on the substrate;
a first buffer layer on the light-blocking layer;
an active layer on the first buffer layer;
a gate electrode on the active layer;
at least one conductive structure between the first buffer layer and the active layer; and
a second buffer layer between the first buffer layer and the active layer, the second buffer layer covering the conductive structure.

23. The display apparatus of claim 22, wherein the light-emitting element includes:
a first electrode electrically connected to the thin-film transistor;
a light-emitting layer on the first electrode; and
a second electrode on the light-emitting layer.
